(19) United States
(12) Patent Application Publication
(10) Pub. No.: US 2020/0194643 A1
(43) Pub. Date: Jun. 18, 2020

(54) OPTICAL MODULE CARRIER

(71) Applicant: I-CHIUN PRECISION INDUSTRY CO., LTD., New Taipei City (TW)

(72) Inventors: Ching-An WU, New Taipei City (TW); Yu-Shiou LI, New Taipei City (TW)

(21) Appl. No.: 16/217,325

(22) Filed: Dec. 12, 2018

(51) Int. Cl. H01L 33/62; G02B 7/02

(52) U.S. Cl. CPC H01L 33/62; H01L 33/58; G02B 7/02

(57) ABSTRACT

An optical module carrier includes an insulation base and a lead frame, the insulation base has a vertical wall, a carrying part is extended from an inner side of the vertical wall, a functional area is formed through being surrounded by an inner side of the carrying part, a lens accommodation area is formed through being surrounded by the vertical wall and defined to be above the carrying part; the lead frame is partially embedded in the insulation base; a gel filling passage is formed on the vertical wall and located at an outer periphery of an optical lens, the gel filling passage is downwardly oriented along the vertical wall, bent and extended to the optical lens and exposed between distal ends of electric conductive pins in the insulation base. Accordingly, advantages of compact structure, small volume and low production cost are provided.

### BACKGROUND OF THE INVENTION

### Field of the Invention

The present invention relates to a carrier technology, especially to an optical module carrier.

### Description of Related Art

Electric components can be manufactured through being directly formed by utilizing lasers for enabling the sizes of the electric components to be greatly reduced, the theory is that plastic units/circuit boards are electrically connected, so that functions such as antenna, support, shield and protect can be provided, thereby forming a 3D-MID (3 dimension molded interconnection device), and an advantage of providing a manufacturing trend having features of short procedure, high precision and being thin and small in sizes can be provided.

However, a layout established through being directly formed by utilizing the lasers may easily to be scratched or cause short circuit due to an external impact. Moreover, the manufacturing procedure adopting the laser for direct formation is costly, especially when being applied in a ceramic substrate, so that a plate-like design can only be adopted, and requirements of customizing substrate cannot be satisfied, thus disadvantages of have limitations in design and being costly are caused.

Accordingly, the applicant of the present invention has devoted himself for improving the mentioned disadvantages.

### SUMMARY OF THE INVENTION

The present invention is to provide an optical module carrier, which has advantages of compact structure, small volume and low production cost.

Accordingly, the present invention provides an optical module carrier, which is used for carrying a chip and an optical lens, and includes an insulation base and a lead frame, the insulation base has a vertical wall, a carrying part is extended from an inner side of the vertical wall, a functional area allowing the chip to be disposed is formed through being surrounded by an inner side of the carrying part, a lens accommodation area is formed through being surrounded by the vertical wall and defined to be above the carrying part, and the lens accommodation area is served to allow the optical lens to be disposed; the lead frame is partially embedded in the insulation base, and the lead frame has a plurality of electric conductive pins formed below the optical lens; at least one gel filling passage is formed on the vertical wall and located at an outer periphery of the optical lens, the gel filling passage is downwardly oriented along the vertical wall, bent and extended to the optical lens and exposed between distal ends of the electric conductive pins in the insulation base.

In comparison with related art, the present invention has advantageous features as follows. A guiding inclined surface is formed in the gel filling passage, so that an electric conductive gel can be facilitated to be filled so as to flow therein; with the electric conductive pins being made of an alloy of molybdenum and copper or an alloy of tungsten and copper, a finished product can be effectively prevented from being deformed; and with the insulation base being integrally formed, the structural strength can be enhanced and the whole height can be lowered.

### BRIEF DESCRIPTION OF DRAWING

FIG. 1 is a perspective view showing the appearance of an optical module carrier according to one embodiment of the present invention;

FIG. 2 is a cross sectional view of FIG. 1 taken along a 2-2 line;

FIG. 3 is a cross sectional view of FIG. 1 taken along a 3-3 line;

FIG. 4 is a top view showing the optical module carrier being combined with the optical lens according to one embodiment of the present invention;

FIG. 5 is a cross sectional view of FIG. 4 taken along a 5-5 line;

FIG. 6 is a perspective view showing the appearance of the optical module carrier according to another embodiment of the present invention;

FIG. 7 is a cross sectional view of FIG. 6 taken along a 7-7 line;

FIG. 8 is a top view showing the optical module carrier being combined with the optical lens according to another embodiment of the present invention; and

FIG. 9 is a cross sectional view of FIG. 8 taken along a 9-9 line.

### DETAILED DESCRIPTION OF THE INVENTION

Preferred embodiments of the present invention will be described with reference to the drawings.

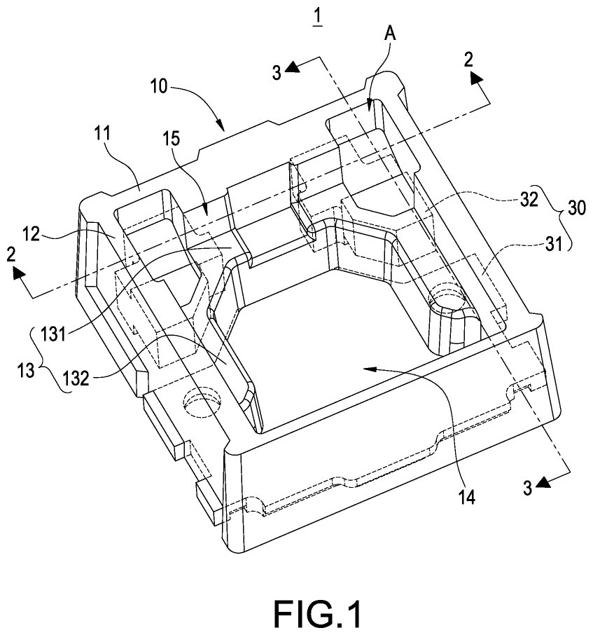

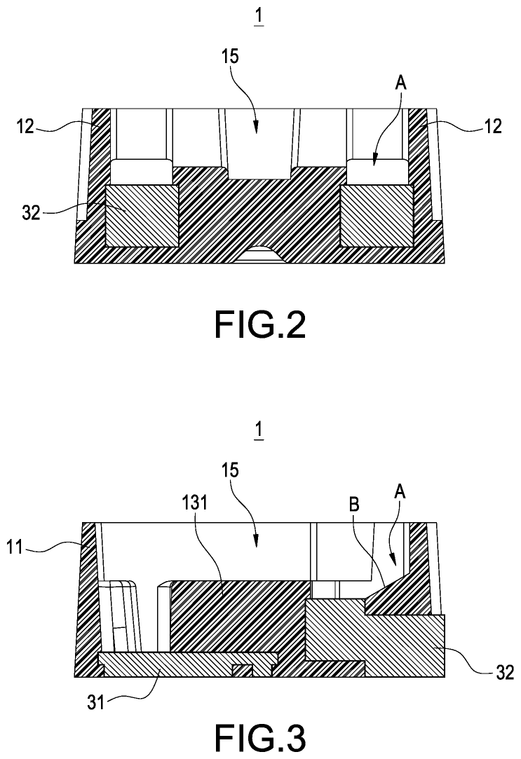

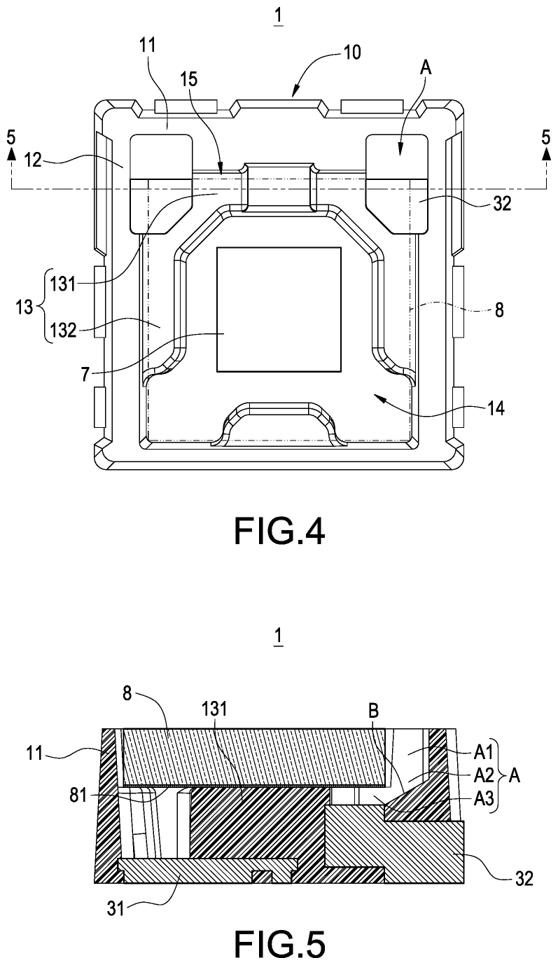

Please refer from FIG. 1 to FIG. 5, the present invention provides an optical module carrier used for carrying a chip 7 and an optical lens 8, wherein, the chip 7 can be a light emitting chip, and the optical lens 8 can be a filter lens. The optical module carrier 1 mainly includes an insulation base 10 and a lead frame 30.

The insulation base 10 can be made of a plastic material having an excellent insulating property, and the appearance thereof can be formed with various geometrical shapes. According to this embodiment, a hollow rectangular member is adopted for providing a clear disclosure, but what shall be addressed is that the scope of the present invention not limited to the above-mentioned hollow rectangular member. The insulation base 10 mainly has two first vertical walls 11 and two second vertical walls 12. The first vertical walls 11 are oppositely arranged, and the second vertical walls 12 and the first vertical walls 11 are adjacently arranged and connected to each other. A carrying part 13 is formed and extended from the second vertical walls 12 and an inner side of the adjacent first vertical wall 11; according to this embodiment, the carrying part 13 mainly has a first piece 131 and two second pieces 132, a U-like shape is formed through being surrounded by the first piece 131 and the second pieces 132, the first piece 131 is inwardly extended from the inner side of the first vertical wall 11, and the second piece 132 is inwardly extended from an inner side of the second vertical wall 12 and connected to one end of the first piece 131.

A functional area 14 allowing the chip 7 to be disposed is formed between an inner side of the carrying part 13 and the first vertical wall 11 at the front, a lens accommodation area 15 is formed through being surrounded by the first vertical walls 11 and the second vertical walls 12 and defined to be above the carrying part 13, thereby enabling the optical lens 8 to be disposed in the lens accommodation area 15.

The lead frame 30 can be made of a metal material having an excellent electric conductivity, and the metal material is preferably to be an alloy of molybdenum and copper or an alloy of tungsten and copper, performances of the alloys are provided in Table 1 and Table 2, wherein the heat conductivity and the heat expansion coefficient are both defined at a temperature of 25 degrees Celsius, the lead frame 30 is partially embedded through the insulation base 10; according to this embodiment, the lead frame 30 mainly has a first electric conductive pin 31 and two second electric conductive pins 32, the first electric conductive pin 31 and the second electric conductive pins 32 are all formed below the optical lens 8, wherein the first electric conductive pin 31 is formed in a plate-like status and located at a location directly below the functional area 14 of the insulation base 10, the second electric conductive pins 32 are both formed in a step-like status and located at two corners of the insulation base 10 and arranged at a rear side of the functional area 14.

TABLE 1
The performance of the alloy of molybdenum and copper

| | | | | | Heat |
|---|---|---|---|---|---|
| | Molyb- | | | Heat | expansion |
| | denum | Copper | Density | conductivity | coefficient |
| Composition | (Wt %) | (Wt %) | (g/cm³) | (W/M · K) | (10⁻⁶/K) |
| Mo85Cu15 | 85 ± 1 | balanced | 10 | 160-180 | 6.8 |
| Mo80Cu20 | 80 ± 1 | balanced | 9.9 | 170-190 | 7.7 |
| Mo70Cu30 | 70 ± 1 | balanced | 9.8 | 180-200 | 9.1 |
| Mo60Cu40 | 60 ± 1 | balanced | 9.66 | 210-250 | 10.3 |
| Mo50Cu50 | 50 ± 1 | balanced | 9.54 | 230-270 | 11.5 |
| Mo40Cu60 | 40 ± 1 | balanced | 9.42 | 280-290 | 11.8 |

TABLE 2
The performance of the alloy of tungsten and copper

| | | | | | Heat |
|---|---|---|---|---|---|
| | | | | Heat | expansion |
| | Tungsten | Copper | Density | conductivity | coefficient |
| Composition | (Wt %) | (Wt %) | (g/cm³) | (W/M · K) | (10⁻⁶/K) |
| W90Cu10 | 90 ± 1 | balanced | 17.0 | 180-190 | 6.5 |
| W85Cu15 | 85 ± 1 | balanced | 16.4 | 190-200 | 7.0 |
| W80Cu20 | 80 ± 1 | balanced | 15.6 | 200-210 | 8.3 |
| W75Cu25 | 75 ± 1 | balanced | 14.9 | 220-230 | 9.0 |
| W50Cu50 | 50 ± 1 | balanced | 12.2 | 310-340 | 12.5 |

In additional to the above-mentioned metal materials, other heat conductive materials, for example copper, silicon, aluminum, molybdenum, aluminum oxide, or a compound thereof or an alloy thereof can also be adopted.

A gel filling passage A is formed at an outer periphery of the optical lens 8 and located at a connecting location of the first vertical wall 11 and the second vertical wall 12, the gel filling passage A is served to allow an electric conductive gel (not shown in figures) to be filled in; according to this embodiment, the gel filling passage A mainly has a first filling passage A1, a second filling passage A2 and a third filling passage A3, wherein the first filling passage A1 is downwardly oriented along the first vertical wall 11 and the second vertical wall 12, the second filling passage A2 is communicated with the first filling passage A1 and bent and extended from a distal end of the first filling passage A1, a guiding inclined surface B is formed on the first vertical wall 11, the third filling passage A3 is communicated with the second filling passage A2 and extended to a location below the optical lens 8 and exposed between distal ends of the second electric conductive pins 32 in the insulation base 10.

The optical lens 8 further has an ITO (indium tin oxide) electric conductive film 81, and the ITO electric conductive film 81 is formed on a bottom surface of the optical lens 8 and partially exposed in the third filling passage A3 of the gel filling passage A.

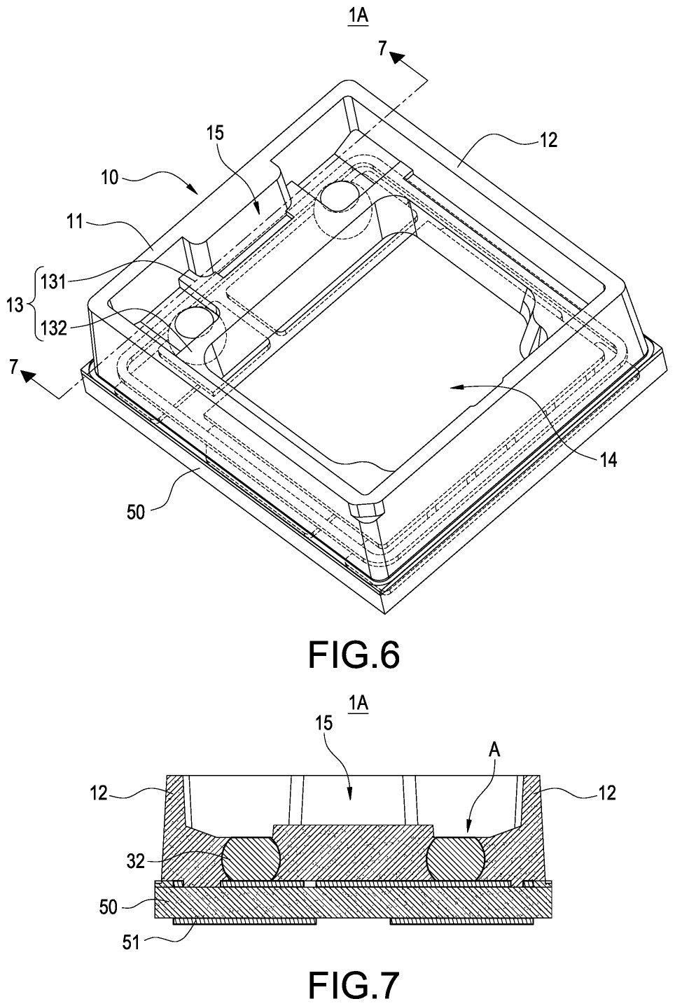

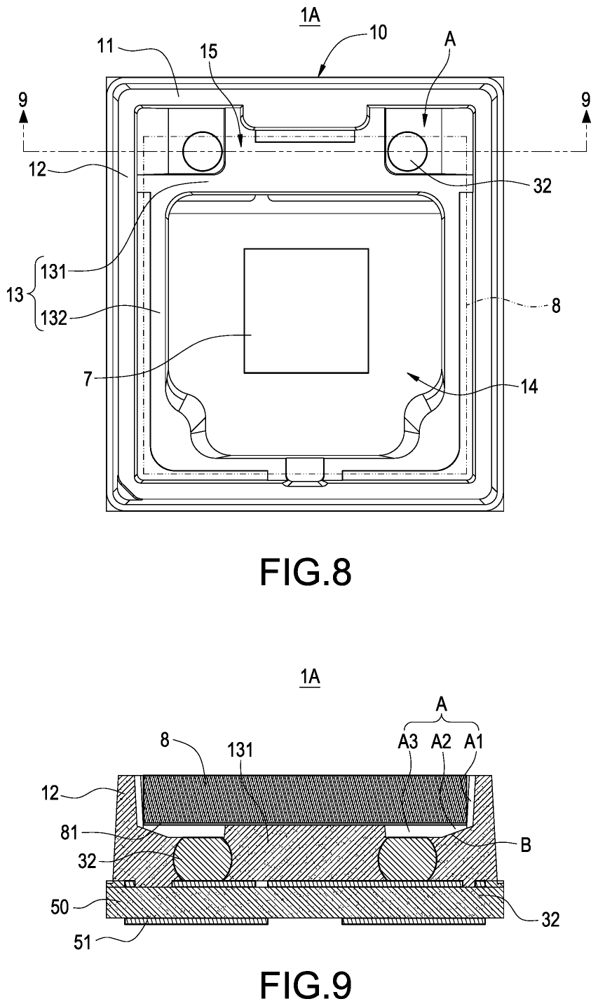

Please refer from FIG. 6 to FIG. 9, which disclose another embodiment of the optical module carrier provided by the present invention. According to the another embodiment, an optical module carrier 1A further includes a ceramic seat 50. The ceramic seat 50 is connected at a bottom end of the insulation base 10, a top surface and a bottom surface thereof are coated with a plurality of electric conductive sheets 51, and the electric conductive sheets 51 arranged at the top are electrically connected to the electric conductive pins 31, 32. According to the another embodiment, the second electric conductive pins 32 are formed in a spherical status and located at two corners of the insulation base 10 and arranged at the rear side of the functional area 14. Moreover, according to the another embodiment, the guiding inclined surface B is formed on the second vertical wall 12. As such, the same effects achieved by the previous embodiment can also be provided. Accordingly, the optical module carrier provided by the present invention is novel and more practical in use comparing to prior arts.

Although the present invention has been described with reference to the foregoing preferred embodiment, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. An optical module carrier, used for carrying a chip and an optical lens, and including:
an insulation base, having a vertical wall, wherein a carrying part is extended from an inner side of the vertical wall, a functional area allowing the chip to be disposed is formed through being surrounded by an inner side of the carrying part, a lens accommodation area is formed through being surrounded by the vertical wall and defined to be above the carrying part, and the lens accommodation area is served to allow the optical lens to be disposed; and
a lead frame, partially embedded in the insulation base and having a plurality of electric conductive pins, wherein the electric conductive pins are formed below the optical lens;
at least one gel filling passage is formed on the vertical wall and located at an outer periphery of the optical lens, the gel filling passage is downwardly oriented along the vertical wall, bent and extended to the optical lens and exposed between distal ends of the electric conductive pins in the insulation base.

2. The optical module carrier according to claim 1, wherein a guiding inclined surface is formed in the gel filling passage and arranged at a location close to a corner of the optical lens.

3. The optical module carrier according to claim 1, wherein the insulation base is formed as a hollow rectangular member.

4. The optical module carrier according to claim 3, wherein the vertical wall has two first vertical walls and two second vertical walls, the first vertical walls are oppositely arranged, the second vertical walls and the first vertical walls are adjacently arranged and connected to each other, and the carrying part is formed between the second vertical walls and an inner side of one of the first vertical walls.

5. The optical module carrier according to claim 4, wherein the gel filling passage has a first filling passage, a second filling passage and a third filling passage, wherein the first filling passage is downwardly oriented along the first vertical wall and the second vertical wall, the second filling passage is communicated with the first filling passage and bent and extended from a distal end of the first filling passage, a guiding inclined surface is formed on the first vertical wall, the third filling passage is communicated with the second filling passage and extended to a location below the optical lens and exposed between distal ends of the electric conductive pins in the insulation base.

6. The optical module carrier according to claim 4, wherein the carrying part has a first piece and two second pieces, and a U-like shape is formed through being surrounded by the first piece and the second pieces.

7. The optical module carrier according to claim 6, wherein the first piece is inwardly extended from the an inner side of the first vertical wall, and the second piece is inwardly extended from an inner side of the second vertical wall and connected to one end of the first piece.

8. The optical module carrier according to claim 4, wherein the gel filling passage has a first filling passage, a second filling passage and a third filling passage, wherein the first filling passage is downwardly oriented along the first vertical wall and the second vertical wall, the second filling passage is communicated with the first filling passage and bent and extended from a distal end of the first filling passage, a guiding inclined surface is formed on the second vertical wall, the third filling passage is communicated with the second filling passage and extended to a location below the optical lens and exposed between distal ends of the electric conductive pins in the insulation base.

9. The optical module carrier according to claim 1, wherein the lead frame is made of an alloy of molybdenum and copper or an alloy of tungsten and copper.

10. The optical module carrier according to claim 1, wherein the electric conductive pins includes a first electric conductive pin and two electric conductive pins, the first electric conductive pin is formed in a plate-like status and located at a location directly below the functional area, the second electric conductive pins are formed in a step-like status and located at a rear side of the functional area.

11. The optical module carrier according to claim 1, furthering including a ceramic substrate connected at a bottom end of the insulation base, the ceramic substrate has a plurality of electric conductive sheets, and the electric conductive sheets are electrically connected to the electric conductive pins.

12. The optical module carrier according to claim 11, wherein the electric conductive pins include a first electric conductive pin and two electric conductive pins, the first electric conductive pin is formed in a plate-like status and located at a location directly below the functional area, the second electric conductive pins are formed in a spherical status and located at a rear side of the functional area.
